(19) United States
(12) Patent Application Publication
(10) Pub. No.: US 2023/0147757 A1
(43) Pub. Date: May 11, 2023

(54) SPHERICAL SILICA POWDER

(71) Applicant: DENKA COMPANY LIMITED, Tokyo (JP)

(72) Inventors: Takuto OKABE, Kawasaki-shi (JP); Motoharu FUKAZAWA, Sagamihara-shi (JP); Toru ARAI, Sagamihara-shi (JP)

(73) Assignee: DENKA COMPANY LIMITED, Tokyo (JP)

(21) Appl. No.: 17/920,631

(22) PCT Filed: Apr. 22, 2021
(86) PCT No.: PCT/JP2021/016377

§ 371 Date: Oct. 21, 2022

(30) Foreign Application Priority Data
Apr. 24, 2020 (JP) 2020-077291
Sep. 30, 2020 (JP) 2020-164696

(51) Int. Cl. C01B 33/18; C08K 3/36

(52) U.S. Cl. CPC C01B 33/18; C08K 3/36; C01P 2004/32; C01P 2002/74

(57) ABSTRACT

A spherical silica powder which, when heated from 25° C. up to 1000° C. at a rate of 30° C./min, desorbs water molecules in an amount of 0.01 mmol/g or less at 500° C. to 1000° C., and which has a specific surface area of 1 to 30 m²/g.

### TECHNICAL FIELD

The present invention relates to a spherical silica powder having a low dielectric loss tangent.

### BACKGROUND ART

With recent increase in the amount of information communication in the field of communication, use of a high frequency band in electronic equipment, communication equipment and others has been widespread. High frequencies have characteristics such as broadband, straightness and permeability, and in particular, a GHz band having a frequency of 10⁹ or more is actively used. For example, in the field of automobiles, in millimeter wave radars and quasi-millimeter wave radars mounted for collision prevention purposes, high frequencies of 76 to 79 GHz and 24 GHz are used, respectively, and are expected to be further widespread in the future.

Along with application of high frequency bands, there has occurred a problem that a transmission loss of circuit signals increases. The transmission loss is roughly divided into a conductor loss due to the skin effect of wirings and a dielectric loss due to characteristics of a dielectric material of an insulator constituting an electric electronic member such as a substrate. The dielectric loss is proportional to the power of a frequency, the one-half power of the dielectric constant of an insulator, and the power of the dielectric tangent thereof, and therefore the materials for use for devices in high-frequency bands are required to have both a low dielectric constant and a low dielectric loss tangent.

Polymer materials for use for insulator materials generally have a low dielectric constant but many of them have a high dielectric loss tangent. On the other hand, many ceramic materials have opposite characteristics, and ceramic filler-filled polymer materials have been investigated in order to achieve both characteristics (e.g., PTL 1).

Dielectric characteristics of GHz-band ceramic materials are known, for example, by NPL 1, which, however, are all characteristics as sintered substrates. Silica (SiO₂) has a small dielectric constant (3.7), and has a quality factor index Qf (a value calculated by multiplying the reverse of a dielectric loss tangent by a measured frequency) of about 120,000, and is therefore hopeful as a filler material having a low dielectric constant and a low dielectric loss tangent. For facilitating blending in a resin, it is desired that the shape of a filler is closer to a spherical shape, and a spherical silica is easy to synthesize (e.g., PTL 2), and is used in many applications. Consequently, it is desired that a spherical silica is broadly used also in high-frequency band dielectric devices.

However, many polar functional groups such as adsorbed water and silanol groups exist on the surfaces of spherical silica particles, and there is a problem that especially the dielectric loss tangent of the spherical silica particles worsens than the characteristics of the sintered substrate.

As a method for reducing the adsorbed water and the polar functional groups on the surfaces of filler particles, for example, NPL 2 investigates a method of surface treatment with a silane coupling agent, but in 1 to 10 MHz, the dielectric loss tangent could reduce little, and an effect in a millimeter waveband is not explicitly described.

### CITATION LIST

### Patent Literature

PTL 1: JP 2014-24916 (A)
PTL 2: JP 1983-138740 (A)

### Non-Patent Literature

NPL 1: International Materials Reviews Vol. 60, No. 70, Supplementary Data (2015)
NPL 2: IEEE Transactions on Dielectrics and Electrical Insulation Vol. 17, No. 6

### SUMMARY OF INVENTION

### Technical Problem

The present invention is to provide a spherical silica powder having a low dielectric loss tangent.

### Solution to Problem

(1) A spherical silica powder which, when heated from 25° C. up to 1000° C. at a rate of 30° C./min, desorbs water molecules in an amount of 0.01 mmol/g or less at 500° C. to 1000° C., and which has a specific surface area of 1 to 30 m²/g.

(2) The spherical silica powder according to (1) which satisfies B/A of 3.0 or less, wherein A indicates a peak intensity at a wavenumber of 3735 cm⁻¹ to 3755 cm⁻¹ of the silica powder measured according to a diffuse reflection FT-IR method, and B indicates a peak intensity at a wavenumber of 3660 cm⁻¹ to 3680 cm⁻¹ thereof.

(3) The spherical silica powder according to (1) or (2), of which an average degree of circularity is 0.85 or more.

(4) The spherical silica powder according to any one of (1) to (3), which has been surface-treated with a surface treating agent.

(5) The spherical silica powder according to any one of (1) to (4), which is blended in a resin and used.

(6) A resin composition containing the spherical silica powder of any one of (1) to (5) and a resin.

(7) The resin composition according to (6), wherein the resin is one or more kinds selected from a hydrocarbon elastomer, a polyphenylene ether, an aromatic polyene resin, and a bismaleimide resin.

(8) A cured product obtained by curing the resin composition of (6) or (7).

### Advantageous Effects of Invention

According to the present invention, there can be provided a spherical silica powder capable of lowering the dielectric loss tangent of a resin material, for example, a substrate.

### DESCRIPTION OF EMBODIMENTS

Embodiments of the present invention are described below. However, the present invention is not limited to the following embodiments.

When heated from 25° C. up to 1000° C. at a rate of 30° C./min, the silica powder of the present invention desorbs water molecules in an amount of 0.01 mmol/g or less at 500° C. to 1000° C. The amount of water molecules desorbed can be measured, for example, using a temperature-programmed desorption gas analyzer (TDS), in which a silica powder sample is heated from 25° C. at 30° C./min, and from the area value in a range of 500° C. to 1000° C. in the resultant mass chromatogram (m/z=18), the number of desorbed H₂O molecules is calculated. The number of desorbed molecules is preferably 0.008 mmol/g or less, and the lower limit is, though not specifically limited, realistically 0.0001 mmol/g or more.

The silica powder of the present invention is preferably a spherical silica powder which, before surface-treated, satisfies B/A of 3.0 or less wherein A indicates a peak intensity at a wavenumber of 3735 cm⁻¹ to 3755 cm⁻¹ of the silica powder measured according to a diffuse reflection FT-IR method, and B indicates a peak intensity at a wavenumber of 3660 cm⁻¹ to 3680 cm⁻¹ thereof. In general, it is known that a peak at a wavenumber of 3735 cm⁻¹ to 3755 cm⁻¹ is from an isolated silanol group and a peak at a wavenumber of 3660 cm⁻¹ to 3680 cm⁻¹ is from a hydrogen-bonding silanol group. In the present invention, an intensity of a hydrogen-bonding silanol group is specifically noted, and when B/A is 3.0 or less, a dielectric loss tangent of a resin composition can be sufficiently lowered. The lower limit is, though not specifically limited, realistically 0.01 or more. In a surface-treated silica, an isolated silanol group (A) disappears, and therefore it is difficult to accurately evaluate B/A. Consequently, quantification may be made with a silica powder before surface treatment, or quantification may be made after the surface treating agent is evaporated away or decomposed by high-temperature heating or vacuum firing, or by washing with an organic solvent. Regarding the number of desorbed H₂O molecules, a number of desorbed molecules at 500° C. to 1000° C. is important, and for vaporizing and decomposing the surface treating agent, the powder may be fired at a temperature of 500° C. or lower, and the B/A value of the silica powder before surface treatment is the same as that thereof in removal of the treating agent after surface treatment. The presence or absence of a surface treating agent can be evaluated, for example, by mass spectrometry or IR.

The spherical silica powder of the present invention has a specific surface area of 1 to 30 m²/g. When the specific surface area is more than 30 m²/g, blending in a resin is difficult, and when less than 1 m²/g, the dielectric loss tangent reducing treatment effect is low. The specific surface area is preferably 1 to 20 m²/g, more preferably 1 to 16 m²/g.

Preferably, the average degree of circularity of the spherical silica powder of the present invention is 0.85 or more, more preferably 0.90 or more. When the average degree of circularity is less than 0.85, there may occur viscosity increase or fluidity reduction when mixed with a resin, thereby worsening processability or fillability.

Preferably, the density of the spherical silica powder of the present invention is 1.8 to 2.4 g/cm³. When the density is less than 1.8, the powder may contain many pores inside the particles and may be difficult to knead in a resin. When the density is more than 2.4, the silica crystal structure may contain α-quartz and cristobalite, which may have influences on physical properties, for example, the thermal expansion coefficient may increase.

As a raw material silica powder in the present invention, a spherical silica powder having an average circularity degree of 0.85 or more and a specific surface area of 1 to 30 m²/g can be favorably used. One example of a production method for the raw material spherical silica powder is a powder melting method for spheroidizing by passing through a high-temperature region at a temperature equal to or higher than the melting point.

The spherical silica powder of the present invention can be produced by high-temperature heat treatment of a raw material silica powder with fluidizing the powder in an inert atmosphere or by heat treatment of the powder in a reducing reaction field of an electric furnace. The temperature and the time may vary depending on the specific surface area of the raw material silica powder, so far as, when heated from 25° C. up to 1000° C. at a rate of 30° C./min, the powder can desorb water molecules in an amount of 0.01 mmol/g or less at 500° C. to 1000° C., and for example, the raw material silica powder can be treated in a nitrogen or argon atmosphere at 700 to 1000° C. for 1 to 24 hours in a rotary kiln while fluidized therein, and then spontaneously left cooled in the kiln. Regarding the electric furnace of a reducing reaction field, for example, in the case of a carbon furnace for which the furnace material is carbon or in the case where the furnace material is any other than carbon, a raw material silica powder is fired in an atmosphere with a few % hydrogen added thereto. After cooled down to 200° C. or lower, the resultant powder is dried in a vacuum drier and thereafter collected in a moisture-proof aluminum bag.

According to the above-mentioned production method, the adsorbed water and the polar functional group on the surface of a spherical silica powder can be reduced without changing the powder characteristics of a specific surface area. After production, even when stored, for example, at a high humidity, for example, in a 40° C.-90% environment for 1 month, it is expected that the amount of the adsorbed water and the polar functional group on the surface of the particles does not change so much as to affect the increase in the dielectric loss tangent of the spherical silica.

The production method can be provided with a step of classifying the powder so as to obtain a desired specific surface area and a desired average particle size. When the heating temperature is 1000° C. or lower, the specific surface area and the average particle size do not change before and after heating, and therefore it is desirable that the classifying step is carried out before heating to attain the desired specific surface area and average particle size, and then heat treatment is carried out.

The resultant powder can be surface-treated with a surface treating agent to further reduce the surface polar group and reduce the dielectric loss tangent. In addition, improvement of affinity and adhesiveness with a resin interface can be expected. The surface treating agent is preferably one having a good compatibility with the resin species to be added and hardly leaving a polar functional group after surface treatment. Examples thereof include epoxysilanes such as γ-glycidoxypropyltriethoxysilane and β-(3,4-epoxycyclohexyl)ethyltrimethoxysilane, aminosilanes such as aminopropyltriethoxysilane and N-phenylaminopropyltrimethoxysilane, vinylsilanes such as vinyltrimethoxysilane, acrylsilanes such as acryloxytrimethoxysilane, and silazanes such as hexamethyldisilazane. The amount to be added of a treating agent having a large amount many polar functional groups, such as aminosilaus or acrylsilaus, is preferably as small as possible, and is, for example, 1 part by mass or less relative to 100 parts by mass of the spherical silica powder. After surface treatment, preferably, the powder is again collected in a moisture-proof aluminum bag.

Impurities such as alkali metals of Na, Li or K and metal elements of Fe that may be contained in the spherical silica powder of the present invention is preferably as small as possible from the viewpoint of dielectric loss tangent reduction. Also the other impurities are preferably reduced as much as possible.

Regarding the storing method for the spherical silica powder of the present invention having a reduced dielectric loss tangent, preferably, the powder is stored using a moisture-proof bag having a moisture permeability of 0.1 (g/m²·24 h) or less under the condition B (temperature 40° C., relative humidity 90%) of JIS Z 0208-1976, for example, a moisture-proof aluminum bag or a PET/Al/PE laminate bag.

By blending and mixing the spherical silica powder of the present invention with any other powder differing in the specific surface area, the average particle size and the composition, a mixed powder can be obtained. By providing a mixed powder, the dielectric constant, the dielectric loss tangent, the thermal expansion coefficient, the thermal conductivity and the filling rate can be readily controlled when blended with a resin.

The spherical silica powder of the present invention and the optionally added mixed powder can be used, for example, by blending in a resin. Namely, the present invention is preferably a resin composition containing the spherical silica powder and a resin. Also preferably, the present invention is a cured product to be produced by curing the resin composition. Examples of the resin usable in the present invention include polyethylene, polypropylene, epoxy resin, silicone resin, phenol resin, melamine resin, urea resin, unsaturated polyester, fluorine resin, polyamide such as polyimide, polyamide imide and polyether imide, polyester such as polybutylene terephthalate and polyethylene terephthalate, polyphenylene sulfide, wholly aromatic polyester, polysulfone, liquid crystal polymer, polyether sulfone, polycarbonate, maleimide-modified resin, ABS resin, AAS (acrylonitrile-acryl rubber-styrene) resin, and AES (acrylonitrile-ethylene-propylene-diene rubber-styrene) resin.

Especially in use as a substrate material or an insulating material for high frequencies, the spherical silica powder of the present invention and the optionally added mixed powder can be blended in a known low dielectric resin for use in the present application. Specifically in use here, the powder is blended in a resin mentioned below, then optionally crosslinked and cured. As such a resin, for example, one or more selected from a hydrocarbon elastomer, a polyphenylene ether, an aromatic polyene resin and a bismaleimide resin are usable. Among these, a hydrocarbon elastomer, a polyphenylene ether and a bismaleimide resin are preferred. A mass ratio of the spherical silica powder or the mixed powder to the resin can be an arbitrary one, but is preferably within a range of 5/95 to 80/20, more preferably within a range of 5/95 to 70/30.

### <Hydrocarbon Elastomer>

Among the hydrocarbon elastomer, a conjugated diene polymer is preferred. Among the conjugated diene polymer, 1,2-polybutadiene is preferred. The hydrocarbon elastomer favorably usable here can have a number-average molecular weight of 1000 or more, preferably 10,000 or more. Examples of the hydrocarbon elastomer include one or plural elastomers selected from an ethylene or propylene elastomer, a conjugated diene polymer, an aromatic vinyl compound-conjugated diene block copolymer or random copolymer, and hydrides (hydrogenated products) thereof. The ethylene elastomer includes an ethylene-α-olefin copolymer such as an ethylene-octene copolymer and an ethylene-1-hexene copolymer, and EPR and EPDM. The propylene elastomer includes an atactic polypropylene, low-stereoregular polypropylene, and a propylene-α-olefin copolymer such as a propylene-1-butene copolymer.

### <Conjugated Diene Polymer>

The conjugated diene polymer includes a polybutadiene and a 1,2-polybutadiene. Examples of the aromatic vinyl compound-conjugated diene block copolymer or random copolymer, and hydrides (hydrogenated products) thereof include SBS, SIS, SEBS, SEPS, SEEPS, and SEEBS. Examples of the 1,2-polybutadiene favorably usable here are available as products by JSR Corporation, and are available as product names of liquid polybutadiene: Product Names B-1000, 2000, 3000 from Nippon Soda Co., Ltd. Examples of the 1,2-polybutadiene structure-containing copolymer also favorably usable here include “Ricon 100” by TOTAL CRAY VALLEY Corporation.

### <Polyphenylene Ether>

As the polyphenylene ether, employable are commercially-available known polyphenylene ethers. The number-average molecular weight of the polyphenylene ether is any arbitrary one, and in consideration of the moldability of the blended composition, the number-average molecular weight is preferably 10,000 or less, most preferably 5,000 or less. The number-average molecular weight can be preferably 500 or more. In the case of addition for curing the blended composition, the molecular terminal of the polymer is preferably modified, and/or the polymer preferably has plural functional groups in one molecule. The functional group includes an allyl group, a vinyl group and an epoxy group. The functional group is preferably a radical-polymerizing functional group. The radical-polymerizing functional group is preferably a vinyl group. The vinyl group is preferably a (meth)acrylic group or an aromatic vinyl group. Further, a bifunctional polyphenylene ether modified with a radical-polymerizing functional group at both ends of the molecular chain is preferred. As such a polyphenylene ether, usable are Noryl (registered trademark) SA9000 by SABIC Corporation and a bifunctional polyphenylene ether oligomer (OPE-25t) by Mitsubishi Gas Chemical Company, Inc.

### <Aromatic Polyene Resin>

The aromatic polyene resin includes a divinylbenzene-type reactive polybranched copolymer (PDV) by Nittetsu Chemical & Material Co., Ltd. Such a PDV is described in, for example, a journal “Synthesis of Polyfunctional Aromatic Vinyl Copolymer and Development of Novel IPN-type Low Dielectric Loss Material Using the Copolymer” (Masanao Kawabe, et al., Journal of Japan Institute of Electronics Packaging, p. 125, Vol. 12, No. 2 (2009)). The aromatic polyene resin includes an aromatic polyene polymer resin having the above-mentioned polyene monomer as a main constituent unit.

### <Bismaleimide Resin>

The maleimides and bismaleimides usable in the present invention are described, for example, in WO2016/114287 (A1) and JP 2008-291227 (A), and are available, for example, from Daiwa Kasei Industry Co., Ltd., and Designer Molecules Inc. These maleimide group-containing compounds are, from the viewpoint of solubility in organic solvent, high-frequency characteristics, high adhesiveness with conductors, and prepreg moldability, preferably bismaleimides. These maleimide group-containing compounds can also be used as polyaminobismaleimide compounds, from the viewpoint of solubility in organic solvent, high-frequency characteristics, high adhesiveness with conductors, and prepreg moldability. The polyaminobismaleimide compound can be obtained, for example, by Michael addition reaction of a compound having two maleimide groups at the terminal and an aromatic diamine compound having two primary amino groups in the molecule.

For use along with the resin, the spherical silica powder and the mixed powder of the present invention can be crosslinked and cured with the following crosslinking material or curing agent. The crosslinking material includes maleic anhydride, glycidyl (meth)acrylate, glycidyl (meth)acrylate, triallyl isocyanurate, tri(meth)acryl isocyanurate and trimethylolpropane tri(meth)acrylate. For attaining a high crosslinking efficiency in a small amount of addition, use of a crosslinking material having a difunctional or higher polyfunctional group is preferred, and examples thereof include triallyl isocyanurate (TALC) and trimethylolpropane tri(meth)acrylate. The maleimide resin and the bismaleimide resin are preferred crosslinking materials for the other resins than maleimide resins and bismaleimide resins. For the resins other than polyphenylene ether, the above-mentioned polyphenylene ether is used as a preferred crosslinking material. The amount of the crosslinking material can be within a range of 0.1 to 30 parts by mass relative to 100 parts by mass of the resin, preferably 0.1 to 10 parts by mass.

### <Curing Agent>

Regarding the usable curing agent, any known curing agent heretofore usable for polymerization or curing of aromatic polyenes or aromatic vinyl compounds can be used. Examples of such a curing agent include a radical polymerization initiator, a cationic polymerization initiator, and an anionic polymerization initiator, and a radical polymerization initiator is preferably used. Preferred are organic peroxide-type and azo-type polymerization initiators, and these can be freely selected depending on the use and the condition. Catalogues describing organic peroxides can be downloaded from NOF website, for example, the following.
https://www.nof.co.jp/business/chemical/product01a.html
https://www.nof.co.jp/business/chemical/product01b.html
http s://www.nof.co.jp/business/chemical/product01c.html

In addition, organic peroxides are described also in catalogues by FUJIFILM Wako Pure Chemical Corporation and Tokyo Chemical Industry Co., Ltd. The curing agent usable in the present invention is available from these companies. In addition, known photopolymerization initiators using light, UV rays or radiations are also usable as the curing agent. The curing agent using a photopolymerization initiator includes a photoradical polymerization initiator, photocationic polymerization initiator and a photoanionic polymerization initiator. Such photopolymerization initiators are available, for example, from Tokyo Chemical Industry Co., Ltd. Further, curing with radiations or electron beams themselves is possible. In addition, not containing a curing agent but crosslinking and curing by thermal polymerization of the contained raw material is also possible. The amount of the curing agent to be used is not specifically limited, but is, in general, preferably 0.01 to 10 parts by mass relative to 100 parts by mass of the resin (preferably excluding a curing agent and a solvent). In the case of using a peroxide-type or azo-type polymerization initiator, curing treatment is carried out at a suitable temperature for a suitable period of time in consideration of the half-life thereof. The condition in the case can be an arbitrary one depending on the curing agent, but in general, a temperature range of approximately 50° C. to 180° C. is suitable.

Compositions of the above-mentioned various resins, crosslinking materials and/or curing agents for use in the case of using the spherical silica powder of the present invention and the mixed powder especially for substrate materials or insulating materials for high frequencies, and cured products thereof are described, for example, in the following patent publications: JP 1996-208856 (A), JP 2017-75270 (A), JP 2009-167268 (A), JP 2011-68713 (A), JP 2018-131519 (A), JP 2016-534549 (A), JP 2017-57352 (A), WO 2016-175325 (Al), WO 2016-175326 (A1), and WO 2018-111337 (A).

The proportion of the spherical silica powder and the optionally added mixed powder in the resin (resin composition) can be appropriately selected in accordance with the intended physical properties such as dielectric constant and dielectric loss tangent. For example, the amount to be used of the resin is appropriately selected within a range of 10 to 10000 parts by mass relative to 100 parts by mass of the spherical silica powder. When the density of the resin is 1.2 g/cm³, the volume ratio of the resin can be appropriately selected within a range of 1.8 to 94.3%.

By blending the spherical silica powder of the present embodiment in a resin, the dielectric loss tangent of the resin sheet after powder blending can be lowered. In addition, the resin sheet containing, as blended therein, the spherical silica powder of the present embodiment has a low viscosity and has good fluidity, and is therefore excellent in moldability.

### EXAMPLES

Hereinunder the present invention is described more specifically by means of Examples, but the present invention is not limited to the Examples.

### [Raw Material Silica Powder 1]

Directly without heat treatment, a spherical silica (FB-5D by DENKA COMPANY LIMITED, specific surface area 2.3 m²/g) was evaluated in the same manner as in Example 1 mentioned below. The evaluation results are shown in Table 1. The dielectric loss tangent of a resin sheet of the raw material powder 1 was 8.0×10⁻⁴ when polyethylene (PE) was used as a resin, and was 6.1×10⁻⁴ when polypropylene (PP) was used as a resin.

### [Raw Material Silica Powder 2]

Directly without heat treatment, a spherical silica (SFP-30M by DENKA COMPANY LIMITED, specific surface area 6.0 m²/g) was evaluated in the same manner as in Example 1 mentioned below. The evaluation results are shown in Table 1. The dielectric loss tangent of a resin sheet (PE) of the raw material silica powder 2 was 1.4×10⁻³.

### [Raw Material Silica Powder 3]

Directly without heat treatment, a spherical silica (SFP-20M by DENKA COMPANY LIMITED, specific surface area 11.5 m²/g) was evaluated in the same manner as in Example 1 mentioned below. The evaluation results are shown in Table 1. The dielectric loss tangent of a resin sheet (PE) of the raw material silica powder 3 was 9.5×10⁻³.

### [Raw Material Silica Powder 4]

Directly without heat treatment, a spherical silica (UFP-30 by DENKA COMPANY LIMITED, specific surface area 30.0 m²/g) was evaluated in the same manner as in Example 1 mentioned below. The evaluation results are shown in Table 1. The dielectric loss tangent of a resin sheet (PE) of the raw material silica powder 4 was 1.7×10⁻³.

### Example 1

As a raw material silica, 50 g of the raw material silica powder 1 (FB-5D by DENKA COMPANY LIMITED, specific surface area 2.3 m²/g) was put into a quartz glass-made cylindrical container, and the cylindrical container was filled in a mullite-made rotary kiln, and heat-treated in a nitrogen atmosphere for 2 hours at a temperature inside the rotary kiln, 900° C. After the heat treatment, this was cooled down until the inside of the kiln reached 200° C. or lower, and dried for 24 hours using a vacuum drier (in an atmosphere lower than 120° C.-133 Pa). Until just before various evaluations, this was stored in a stand pack of an aluminum pack (PET/Al/PE laminate bag by SEISANNIPPONSHA, Ltd.) The evaluation results are shown in Table 2. The dielectric loss tangent of the resin sheet (PE) was 4.7×10⁻⁴.

### Examples 2, 3

Heat treatment and evaluation were carried out in the same manner as in Example 1 except that the temperature and the time for heat treatment were as in Table 2. The evaluation results are shown in Table 2.

### Example 4

As a raw material silica, 50 g of the raw material silica powder 1 (FB-5D by DENKA COMPANY LIMITED, specific surface area 2.3 m²/g) was put into a quartz glass-made cylindrical container, and the cylindrical container was filled in a mullite-made rotary kiln, and heat-treated in a nitrogen atmosphere for 2 hours at a temperature inside the rotary kiln, 900° C. After the heat treatment, this was cooled down until the inside of the kiln reached 200° C. or lower, and dried for 24 hours using a vacuum drier (in an atmosphere lower than 120° C.-133 Pa). As a surface treating agent, 1 part by mass of hexamethyldisilazane (SZ-31; HMDS, by Shin-Etsu Chemical Co., Ltd.) was added to 100 parts by mass of the collected sample. The added powder was mixed with an oscillating mixer by Resodyn Corporation, dried for 24 hours using a vacuum drier (in an atmosphere lower than 120° C.-133 Pa), and stored in an aluminum pack until just before various evaluations in the same manner as in Example 1. The evaluations were carried out in the same manner as in Example 1. The evaluation results are shown in Table 2.

### Example 5

Heat treatment and evaluation were carried out in the same manner as in Example 4 except that vinyltrimethoxysilane (KBM-1003; vinyl, by Shin-Etsu Chemical Co., Ltd.) was used as the surface treating agent.

### Example 6

Heat treatment and evaluation were carried out in the same manner as in Example 1 except that the raw material silica powder 2 (SFP-30M by DENKA COMPANY LIMITED, specific surface area 6.0 m²/g) was used as the raw material silica. The evaluation results are shown in Table 2.

### Example 7

Heat treatment and evaluation were carried out in the same manner as in Example 1 except that a polypropylene powder was used in evaluation of the dielectric characteristics. The evaluation results are shown in Table 2.

### Example 8

As a raw material silica, 50 g of the raw material silica powder 1 (FB-5D by DENKA COMPANY LIMITED, specific surface area 2.3 m²/g) was put into an aluminum crucible, and using “Hi multi” (carbon furnace) by Fujidempa Kogyo Co., Ltd., this was heat-treated in a nitrogen atmosphere at a temperature inside the electric furnace, 1000° C. for 4 hours. After the heat treatment, this was cooled down until the inside of the furnace reached 200° C. or lower, and dried for 24 hours using a vacuum drier (in an atmosphere lower than 120° C.-133 Pa). Until just before various evaluations, this was stored in a stand pack of an aluminum pack (PET/Al/PE laminate bag by SEISANNIPPONSHA, Ltd.) The evaluation results are shown in Table 2.

### Example 9

Heat treatment and evaluation were carried out in the same manner as in Example 8 except that the raw material silica powder 2 (SFP-30M by DENKA COMPANY LIMITED, specific surface area 6.0 m²/g) was used as the raw material silica and the heating temperature and the atmosphere were as in Table 2. The evaluation results are shown in Table 2.

### Example 10

Heat treatment and evaluation were carried out in the same manner as in Example 9 except that the temperature and the time for heat treatment and the atmosphere were as in Table 2. The evaluation results are shown in Table 2.

### Example 11

Heat treatment and evaluation were carried out in the same manner as in Example 1 except that the raw material silica powder 3 (SFP-20M by DENKA COMPANY LIMITED, specific surface area 11.5 m²/g) was used as the raw material silica and the temperature and the time for heat treatment were as in Table 2. The evaluation results are shown in Table 2.

### Example 12

Heat treatment and evaluation were carried out in the same manner as in Example 1 except that the raw material silica powder 4 (UFP-30 by DENKA COMPANY LIMITED, specific surface area 30.0 m²/g) was used as the raw material silica and the temperature and the time for heat treatment were as in Table 2. The evaluation results are shown in Table 2.

### Example 13

Heat treatment and evaluation were carried out in the same manner as in Example 1 except that the temperature and the time for heat treatment were as in Table 2. The evaluation results are shown in Table 2.

### Comparative Examples 1 to 4

Heat treatment and evaluation were carried out in the same manner as in Example 1 except that the temperature and the time for heat treatment, the raw material silica powder and the atmosphere were as in Table 3. The evaluation results are shown in Table 3.

Characteristics of the samples were evaluated according to the following methods. The evaluation results are shown in Tables 1 to 3.

### [Average Degree of Circularity]

A powder was fixed on a sample stand with a carbon tape, then coated with osmium, and photographed with a scanning electron microscope (JSM-7001F SHL, by JEOL Corporation) at a magnification power of 500 to 50000 times and a resolution of 1280×1024 pixels, and the resultant pictures were taken into a personal computer. Using an image analyzer (Image-Pro Premier Ver. 9.3 by Nippon Roper Corporation), the images were analyzed to calculate the projected surface area (S) of the particles (powder particles) and the projected peripheral length (L) of the particles, and the degree of circulation was calculated according to the following formula (1). For the raw material silica FB-5D, 200 particles having a size of 1 to 10 μm were arbitrarily selected, and for the raw material silica SFP-30M, 200 particles having a size of 0.2 to 1 μm were arbitrarily selected, and the degree of circularity of each of these particles was calculated. The found data were averaged to be an average degree of circularity of the sample.

Degree of Circularity=4nS/L² Formula (1)

### [Density]

1.2 g of a powder was put into a sample cell for measurement, and using a dry-type densitometer (“Accupyc II 1340” by Shimadzu Corporation), the density thereof was measured according to a gaseous (helium) displacement method.

### [Specific Surface Area]

One g of a powder was filled in a cell for measurement, and the specific surface area thereof was measured with a full-automatic specific surface area measuring apparatus (BET one point method) of Macsorb HM model-1201 by Mountech Corporation. The degassing condition before measurement was 200° C. for 10 minutes. The adsorption gas was nitrogen.

### [B/A]

The integrated intensity ratio of B (hydrogen-bonding silanol group) to A (isolated silanol group) was determined as follows. Using a Fourier transform IR spectrophotometer (Frontier IR spectrometer by PerkinElmer Corporation), measurement (resolution 8.0 cm⁻¹, number of scans 32 times) was carried out according to a diffuse reflectance method in an air atmosphere, and on the resultant diffuse reflectance spectrum, a base line was drawn between 3800 and 2875 cm⁻¹, then an isolated silanol group peak intensity at 3735 cm⁻¹ to 3755 cm⁻¹ and a hydrogen-bonding silanol group peak intensity at 3660 cm⁻¹ to 3680 cm⁻¹ were calculated, and the peak intensity ratio was calculated.

[Amount of desorbed Water]

A temperature-programmed desorption gas analyzer (EMD-WA1000S/W; TDS, by ESCO, Ltd.), a sample was heated from 25° C. up to 1000° C., as the temperature of an upper thermocouple, at 30° C./min in an air atmosphere, and from the area value in a range of 500° C. to 1000° C. on the resultant mass chromatogram (m/z=18), the number of desorbed H₂O molecules was calculated. A carbon sheet, a sample powder (10 mg) and a carbon sheet were put on a sample dish in that order, and the measurement was carried out under the condition.

### [Evaluation of Dielectric Characteristics]

A spherical silica powder after heat treatment and a polyethylene (PE) powder (Flothene UF-20_S by Sumitomo Seika Chemicals Co., Ltd.) or a polypropylene (PP) powder (Flowbrene QB200 by Sumitomo Seika Chemicals Co., Ltd.) were weighed so that the filler content of the spherical silica powder could be 40 vol %, and mixed with an oscillating mixer by Resodyn Corporation (acceleration 60 g, treatment time 2 minutes). The resultant mixed powder was weighed to be a predetermined volume fraction (so as to have a thickness of 0.3 mm), put into a mold having a diameter of 3 cm, and, using a hot pressing machine (“IMC-1674-A Model” by Imoto Machinery Co., Ltd.), formed into a sheet under the condition of 140° C., 10 MPa and 15 minutes for PE, and under the condition of 190° C., 10 MPa and 60 minutes for PP, thereby preparing evaluation samples. The thickness of the evaluation sample sheet was 0.3 mm. The shape and the size thereof have no influence on evaluation results, so far as the sample could be mounted on the measurement apparatus. In this, the size of the sample was 1.5 cm square.

Dielectric characteristics measurement was as follows. A 36 GHz cavity resonator (by SAMTECH Corp.) was connected with a vector network analyzer (85107, by Keysight Technologies, Inc.), and a sample (1.5 cm square, thickness 0.3 mm) was set to fill up the hole having a diameter of 10 mm provided in the resonator, and the resonance frequency (f0) and the unloaded Q value (Qu) were measured. At every measurement, the sample was rotated, and the measurement was repeated five times in the same manner. The found data of FO and Qu were each averaged to provide a measured average value. From f0, the dielectric constant, and from Qu, the dielectric loss tangent were calculated using analyzing software (Software by SAMTECH Corp.). The measurement temperature was 20° C., and the humidity was 60% RH.

The dielectric loss tangent of a resin sheet prepared by blending each of the raw material spherical silica powders 1 to 4 with a resin was referred to as a, the dielectric loss tangent of a resin sheet prepared by blending the spherical silica powder of Examples and Comparative Examples with a resin was referred to b, and a reduction ratio (%) of the dielectric loss tangent of the resin sheet itself was determined from the formula (2).

Reduction ratio (%) of dielectric loss tangent of resin sheet itself

={1−(b/a)}×100 Formula (2)

TABLE 1

| | | Raw Material | Raw Material | Raw Material | Raw Material | Raw Material |
|---|---|---|---|---|---|---|
| | | Silica | Silica | Silica | Silica | Silica |
| | Unit | Powder 1 | Powder 1 | Powder 2 | Powder 3 | Powder 4 |
| Kind of Raw Material | — | FB- | FB- | SFP- | SFP- | UFP- |
| Silica Powder | | 5D | 5D | 30M | 20M | 30 |
| Average Degree of | — | 0.95 | 0.95 | 0.96 | 0.95 | 0.97 |
| Circularity | | | | | | |
| Density | g/cm³ | 2.2 | 2.2 | 2.3 | 2.2 | 2.2 |
| Specific Surface Area | m²/g | 2.3 | 2.3 | 6.0 | 11.5 | 30.0 |
| B/A | — | 6.4 | 6.4 | 4.0 | 3.1 | 1.7 |
| Amount of Desorbed | mmol/g | 0.014 | 0.014 | 0.020 | 0.026 | 0.034 |
| Water Molecules | | | | | | |
| Resin Species | — | PE | PP | PE | PE | PE |
| Dielectric Constant | — | 2.8 | 3.0 | 2.8 | 2.7 | 2.5 |
| of Resin Sheet | | | | | | |
| Dielectric Loss Tangent | — | 8.0E−04 | 6.1E−04 | 1.4E−03 | 9.5E−03 | 1.7E−03 |
| of Resin Sheet | | | | | | |

TABLE 2

| | | Exam- | Exam- | Exam- | Exam- | Exam- | Exam- | Exam- |
|---|---|---|---|---|---|---|---|---|
| | Unit | ple 1 | ple 2 | ple 3 | ple 4 | ple 5 | ple 6 | ple 7 |
| Kind of Raw | — | FB- | FB- | FB- | FB- | FB- | SFP- | FB- |
| Material | | 5D | 5D | 5D | 5D | 5D | 30M | 5D |
| Silica | | | | | | | | |
| Powder | | | | | | | | |
| Heating | ° C. | 900 | 900 | 800 | 900 | 900 | 850 | 900 |
| Temperature | | | | | | | | |
| Heating | h | 2 | 4 | 1 | 2 | 2 | 4 | 2 |
| Time | | | | | | | | |
| Atmosphere | — | Nitro- | Nitro- | Nitro- | Nitro- | Nitro- | Nitro- | Nitro- |
| | | gen | gen | gen | gen | gen | gen | gen |
| Surface | — | — | — | — | HMDS | Vinyl | — | — |
| Treatment | | | | | | | | |
| Average | — | 0.95 | 0.95 | 0.96 | 0.95 | 0.94 | 0.96 | 0.95 |
| Degree of | | | | | | | | |
| Circularity | | | | | | | | |
| Density | g/cm³ | 2.2 | 2.2 | 2.2 | 2.2 | 2.2 | 2.2 | 2.2 |
| Specific | m²/g | 2.3 | 2.3 | 2.4 | 2.3 | 2.3 | 6.0 | 2.3 |
| Surface | | | | | | | | |
| Area | | | | | | | | |
| B/A | — | 2.4 | 1.6 | 3.0 | 2.4 | 2.4 | 0.9 | 2.4 |
| Amount of | mmol/g | 0.004 | 0.003 | 0.007 | 0.004 | 0.004 | 0.008 | 0.004 |
| Desorbed | | | | | | | | |
| Water | | | | | | | | |
| Molecules | | | | | | | | |
| Resin | — | PE | PE | PE | PE | PE | PE | PP |
| Species | | | | | | | | |
| Dielectric | — | 2.8 | 2.8 | 2.8 | 2.8 | 2.8 | 2.8 | 3.0 |
| Constant of | | | | | | | | |
| Resin Sheet | | | | | | | | |
| Dielectric | — | 4.7E−04 | 4.5E−04 | 6.2E−04 | 4.5E−04 | 4.2E−04 | 6.1E−04 | 3.7E−04 |
| Loss Tangent | | | | | | | | |
| of Resin | | | | | | | | |
| Sheet | | | | | | | | |
| Reduction | % | 41 | 44 | 23 | 44 | 48 | 56 | 39 |
| Ratio of | | | | | | | | |
| Dielectric | | | | | | | | |
| Loss Tangent | | | | | | | | |

| | Exam- | Exam- | Exam- | Exam- | Exam- | Exam- |
|---|---|---|---|---|---|---|
| | ple 8 | ple 9 | ple 10 | ple 11 | ple 12 | ple 13 |
| Kind of Raw | FB- | SFP- | SFP- | SFP- | UFP- | FB- |
| Material | 5D | 30M | 30M | 20M | 30 | 5D |
| Silica | | | | | | |
| Powder | | | | | | |
| Heating | 1000 | 900 | 1000 | 1000 | 1000 | 750 |
| Temperature | | | | | | |
| Heating | 4 | 4 | 4 | 4 | 20 | 10 |
| Time | | | | | | |
| Atmosphere | Nitro- | Nitro- | Nitro- | Nitro- | Nitro- | Nitro- |
| | gen | gen | gen | gen | gen | gen |
| Surface | — | — | — | — | — | — |
| Treatment | | | | | | |
| Average | 0.94 | 0.95 | 0.94 | 0.95 | 0.92 | 0.95 |
| Degree of | | | | | | |
| Circularity | | | | | | |
| Density | 2.2 | 2.2 | 2.2 | 2.3 | 2.2 | 2.2 |
| Specific | 2.2 | 6.2 | 6.1 | 11.4 | 28.5 | 2.3 |
| Surface | | | | | | |
| Area | | | | | | |
| B/A | 0.6 | 0.4 | 0.5 | 1.2 | 0.2 | 3.8 |
| Amount of | 0.003 | 0.007 | 0.006 | 0.008 | 0.010 | 0.007 |
| Desorbed | | | | | | |
| Water | | | | | | |
| Molecules | | | | | | |
| Resin | PE | PE | PE | PE | PE | PE |
| Species | | | | | | |
| Dielectric | 2.8 | 2.8 | 2.8 | 2.7 | 2.5 | 2.8 |
| Constant of | | | | | | |
| Resin Sheet | | | | | | |
| Dielectric | 3.4E−04 | 5.8E−04 | 4.8E−04 | 6.3E−04 | 8.5E−4 | 5.8E−04 |
| Loss Tangent | | | | | | |
| of Resin | | | | | | |
| Sheet | | | | | | |
| Reduction | 58 | 59 | 66 | 55 | 39 | 28 |
| Ratio of | | | | | | |
| Dielectric | | | | | | |
| Loss Tangent | | | | | | |

TABLE 3

| | | Comparative | Comparative | Comparative | Comparative |
|---|---|---|---|---|---|
| | Unit | Example 1 | Example 2 | Example 3 | Example 4 |
| Kind of Raw Material Silica Powder | — | FB-5D | FB-5D | SFP-30M | FB-5D |
| Heating Temperature | ° C. | 500 | 850 | 400 | 800 |
| Heating Time | h | 2 | 0.5 | 2 | 1 |
| Atmosphere | — | Nitrogen | Nitrogen | Nitrogen | Air |
| Average Degree of Circularity | — | 0.95 | 0.95 | 0.95 | 0.96 |
| Density | g/cm³ | 2.2 | 2.2 | 2.2 | 2.2 |
| Specific Surface Area | m²/g | 2.4 | 2.4 | 6.0 | 2.4 |
| B/A | — | 4.6 | 3.3 | 3.1 | 3.0 |
| Amount of Desorbed Water Molecules | mmol/g | 0.015 | 0.011 | 0.021 | 0.011 |
| Resin Species | — | PE | PE | PE | PE |
| Dielectric Constant of Resin Sheet | — | 2.8 | 2.8 | 2.8 | 2.8 |
| Dielectric Loss Tangent of Resin Sheet | — | 6.8E−04 | 7.2E−04 | 1.2E−03 | 6.9E−04 |
| Reduction Ratio of Dielectric Loss Tangent | % | 15 | 10 | 14 | 14 |

The results are that the resin sheets containing any of the spherical silica powders of Examples 1 to 13 have a more reduced dielectric loss tangent as compared with the resin sheets containing any of the spherical silica powders of Comparative Examples 1 to 4.

### Example 14

As conjugated diene polymers, used were 1,2-polybutadiene (trade name B-1000, liquid polybutadiene by Nippon Soda Co., Ltd.) and a bifunctional polyphenylene ether oligomer (OPE-2St by Mitsubishi Gas Chemical Co., Ltd., number-average molecular weight 1200). A toluene solution product of OPE-2St by Mitsubishi Gas Chemical Co., Ltd. was further diluted with toluene, and a large amount of methanol was added thereto for methanol precipitation, and after drying in air and drying under reduced pressure, the resultant powdery polyphenylene ether oligomer was used here. As a peroxide, Percumyl D by NOF Corporation was sued. 1,2-Polybutadiene, OPE-2St and the peroxide were, combined as in Table 4 (unless otherwise specifically indicated, the unit is part by mass) and dissolved in toluene to prepare a varnish. The powder obtained in Example 10 (SFP-30M-processed powder) was added to the varnish in a ratio of 30% by volume relative to 70% by volume of the resin content (total of 1,2-polybutadiene, OPE-25t) therein, then uniformly mixed by stirring, cast into a Teflon frame, and, while depressurized, gradually heated up to 60° C., and thereafter kept as such for one full day to remove the solvent. The resultant uncured sheet was heated at a rate of 6° C./min while pressed at 2 MPa with a vacuum hot pressing machine, then kept at 220° C. for 1 hour to give a crosslinked sheet (cured product) having a thickness of 0.5 mm. The dielectric characteristics thereof were evaluated in the same manner as in Example 1. As shown in Table 4, the dielectric loss tangent value of the sheet of the present Example was a predominantly lower value as compared with that of Comparative Example 5 to be mentioned below.

### Comparative Example 5

A resin sheet was produced in the same manner as in Example 14 except that a powder unprocessed with SFP-30M was used in place of the powder obtained in Example 10 (SFP-30M-processed powder), and the dielectric characteristics were evaluated in the same manner as in Example 1. The results are shown in Table 4.

TABLE 4

| | | Comparative | Example |
|---|---|---|---|
| | | Example 5 | 14 |
| Blending with | 1,2-Polybutadiene | 70 | 70 |
| Resin | OPE-2St | 30 | 30 |
| | Peroxide (Percumyl D) | 2 | 2 |
| | Toluene | 100 | 100 |
| Blending with | Powder unprocessed | 30 vol % | — |
| Silica Powder | with SFP-30M | | |
| | SFP-30M-processed | — | 30 vol % |
| | powder | | |

| | | |
|---|---|---|
| Dielectric Constant of Resin Sheet | 2.7 | 2.7 |
| Dielectric Loss Tangent of Resin Sheet | 0.002 | 0.0015 |

### INDUSTRIAL APPLICABILITY

The spherical silica powder of the present invention is, when filled in a resin material, usable as a filler capable of reducing the dielectric loss tangent of a substrate as compared with a conventional spherical silica.

1. A spherical silica powder which, when heated from 25° C. up to 1000° C. at a rate of 30° C./min, desorbs water molecules in an amount of 0.01 mmol/g or less at 500° C. to 1000° C., and which has a specific surface area of 1 to 30 m²/g.

2. The spherical silica powder according to claim 1 which satisfies B/A of 3.0 or less, wherein A indicates a peak intensity at a wavenumber of 3735 cm⁻¹ to 3755 cm⁻¹ of the silica powder measured according to a diffuse reflection FT-IR method, and B indicates a peak intensity at a wavenumber of 3660 cm⁻¹ to 3680 cm⁻¹ thereof.

3. The spherical silica powder according to claim 1, of which an average degree of circularity is 0.85 or more.

4. The spherical silica powder according to claim 1, which has been surface-treated with a surface treating agent.

5. The spherical silica powder according to claim 1, which is blended in a resin and used.

6. A resin composition containing the spherical silica powder of claim 1 and a resin.

7. The resin composition according to claim 6, wherein the resin is one or more kinds selected from a hydrocarbon elastomer, a polyphenylene ether, an aromatic polyene resin, and a bismaleimide resin.

8. A cured product obtained by curing the resin composition of claim 6.
